(19) United States
(12) Patent Application Publication
(10) Pub. No.: US 2004/0206999 A1
(43) Pub. Date: Oct. 21, 2004

(54) Metal dielectric semiconductor floating gate variable capacitor

(75) Inventors: John D. Hyde, Corvalis, OR (US); Yanjun Ma, Issaquah, WA (US)

Correspondence Address: David B. Ritchie, THELEN REID & PRIEST LLP, P.O. Box 640640, San Jose, CA, 95164-0640, US

(73) Assignee: Impinj, Inc., a Delaware Corporation

(21) Appl. No.: 10/143,557

(22) Filed: May 9, 2002

(51) Int. Cl. H01L 21/8242; H01L 27/108; H01L 29/76; H01L 31/119; H01L 29/00; H01L 21/20

(52) U.S. Cl. 257/312; 257/314; 257/532; 438/379; 438/239; 438/257

(57) ABSTRACT

A simple metal dielectric semiconductor (MDS) variable capacitor which may be a MOS capacitor uses the drain and source of a floating gate metal dielectric semiconductor field effect transistor connected to the bulk of the semiconductor substrate as one plate of the capacitor and the gate of the transistor as the other plate. The capacitance is voltage dependent and is strongly nonlinear in the depletion region. The accumulation and strong inversion regions are also nonlinear, but to a much smaller degree. The nonlinearity can be significantly reduced by connecting two of the capacitors in series. This series connection also makes possible a capacitor structure with an isolated floating gate connecting the two series capacitors. The charge on the floating gate can be controlled by tunneling and injection to vary the capacitor bias voltage and thus, its capacitance. Alternatively, the capacitors may operate in the accumulation region. In this configuration the accumulation capacitors do not require transistors nor do they require source and drain regions. The capacitance appears between the floating gate and the bulk (well). In other respects they operate as described above.

### FIELD OF THE INVENTION

This invention relates to variable capacitors. More particularly it relates to a metal dielectric semiconductor or metal oxide semiconductor (MOS) floating gate capacitor which may, for example, be fabricated with a standard complementary MOS (CMOS) process providing only pMOS transistors and NMOS transistors (either of which may be configured as capacitors) and connectivity among them.

### BACKGROUND OF THE INVENTION

Recent developments in electronic integration of circuits on integrated circuit chips (ICs) have provided the capability of integrating analog devices onto traditionally digital-only CMOS ICs. With this capability comes the challenge of fabricating other traditional analog components out of the circuitry available for fabrication on CMOS ICs without being forced to modify the standard CMOS processing in order to fabricate the new device. It is undesirable to modify the standard CMOS processing because to do so increases expense, sometimes significantly so, and, in the case of those desiring to build such products with contract manufacturers, reduces or eliminates the number of such contract manufacturers available or willing to build such products.

One type of device which exists in the analog world, but not heretofore in the digital world, is the variable capacitor. Analog variants are sometimes referred to as varicaps or varactors. It would be highly desirable to be able to implement a variable capacitance device in standard CMOS. Such a device could be used to help match the operational characteristics of separate devices, to provide variable or tunable outputs, such as tunable frequency outputs, tunable oscillators, and the like.

### BRIEF DESCRIPTION OF THE INVENTION

In one aspect of the invention, a simple metal dielectric semiconductor (MDS) variable capacitor which may be a MOS capacitor (MOSCAP) uses the drain and source of a floating gate metal dielectric semiconductor field effect transistor connected to the bulk of the semiconductor substrate as one plate of the capacitor and the gate of the transistor as the other plate. The capacitance is voltage dependent and is strongly nonlinear in the depletion region. The accumulation and strong inversion regions are also nonlinear, but to a much smaller degree. Connecting two of the capacitors in series can significantly reduce the nonlinearity. This series connection also makes possible a capacitor structure with an isolated floating gate connecting the two series capacitors. The charge on the floating gate can be controlled, for example by tunneling and injection, to vary the capacitor bias voltage and thus, its capacitance.

In another aspect of the invention, the capacitors operate in the accumulation region and thus do not require source and drain regions. The capacitance appears between the floating gate and the bulk (well). In other respects they operate as described above.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a schematic/cross sectional diagram of a pFET floating gate transistor connected as a MOS capacitor.

FIG. 2 is a plot of the typical CV characteristic of a floating gate pMOS transistor in 0.25 μm CMOS with a 7 nm gate oxide thickness between the substrate and the floating gate.

FIG. 3 is an elevational cross sectional drawing of a pFET floating gate transistor.

FIG. 4 is an electrical schematic diagram of a MOS floating gate variable capacitor in accordance with one embodiment of the present invention.

FIG. 5A is a cross sectional elevational diagram of a MOS floating gate variable capacitor in accordance with the embodiment of the present invention depicted in FIG. 4.

FIGS. 5B and 5C are cross sectional elevational diagrams of MOS floating gate variable capacitors in accordance with alternative embodiments of the present invention.

FIG. 6 is a plot of capacitance vs. voltage (CV) for various levels of charge stored on the floating gate of a MOS floating gate variable capacitor in accordance with one embodiment of the invention.

FIG. 7 is a cross sectional elevational diagram of a MOS floating gate variable capacitor in accordance with an alternative embodiment of the present invention.

### DETAILED DESCRIPTION

Embodiments of the present invention are described herein in the context of a floating gate variable capacitor fabricated on a metal/dielectric/semiconductor structure such as MOS. Those of ordinary skill in the art will realize that the following detailed description of the present invention is illustrative only and is not intended to be in any way limiting. Other embodiments of the present invention will readily suggest themselves to such skilled persons having the benefit of this disclosure. For example, other types of capacitors could also be trimmed by the basic mechanisms disclosed herein. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Synapse transistors are conventional transistors with the following additional attributes: (1) nonvolatile analog weight storage, (2) locally computed bidirectional weight updates, and (3) simultaneous memory reading and writing. Synapse transistors are described, for example, in U.S. Pat. Nos. 5,627,392, 5,825,063, 5,898,613, and 5,990,512 to Diorio et al. Floating-gate MOSFETs are used as the basis for synapse transistors in accordance with one embodiment of the present invention. Synapse transistors use charge stored on a floating gate to represent the nonvolatile analog weight, electron tunneling and hot-electron injection to modify the floating-gate charge bidirectionally, and allow simultaneous memory reading and writing by nature of the mechanisms used to write the memory. The pFET synapse transistor is discussed in detail herein because of its inherent compatibility with standard CMOS processing. Other types of synapse transistors could also be used as will now be appreciated by those of ordinary skill in the art but the pFET synapse transistor is most compatible with standard CMOS processing.

Impact-ionized hot electron injection (IHEI) may be used in pFET synapse transistors to inject electrons onto the floating gate. First, the pFET synapse transistor's floating gate is biased so that current flows in the synapse transistor. This current comprises holes in the inverted channel of the p-type MOSFET. By applying a sufficiently low potential to the synapse transistor's drain relative to its source, the holes are accelerated in the transistor's channel-to-drain depletion region. These holes collide with the semiconductor lattice, liberating an electron-hole pair. The ionized electrons are expelled from the drain region by the channel-to-drain electric field while the favorable drain field collects the holes. Electrons, which are expelled with enough energy from the drain region, may be scattered upward through the silicon dioxide isolation layer toward the floating gate and can overcome the energy gap between the polysilicon floating gate and the silicon dioxide of the isolation layer to be collected on the floating gate. For a more complete discussion of IHEI, see, e.g., C. Diorio, P. Hasler, B. A. Minch and C. Mead, “A floating-gate MOS learning array with locally computed weight updates”, IEEE Trans. Electron Devices, vol. 44, no. 12, pp. 2281-2289 (1997).

Electron tunneling may be accomplished using Fowler-Nordheim tunneling. A second pFET, whose drain, source and well are shorted together, is used to create the tunneling junction. The polysilicon floating gate of this shorted pFET is shared with the injection device described above. By applying a relatively high positive voltage to the shorted well, drain and source, electrons tunnel from the polysilicon floating gate to the well of the transistor. The relatively high positive voltage between the well and the floating gate effectively reduces the oxide barrier thickness, facilitating electron tunneling through the silicon dioxide barrier.

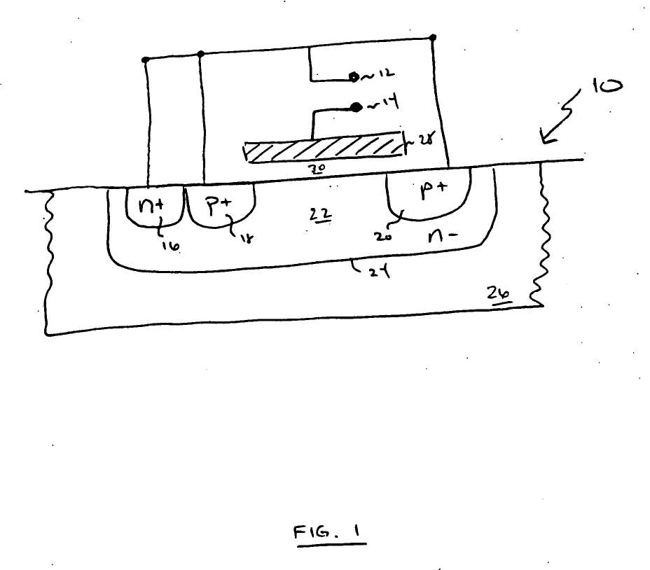

FIG. 1 is schematic diagram of a p-type MOSFET floating gate transistor connected as a capacitor. MOSFET devices such as MOSFET 10 illustrated in FIG. 1 exhibit capacitance between nodes 12 and 14. In this drawing, node 12 is tied to the well contact 16, source 18 and drain 20 of pMOS transistor 22 in an n− well 24 of substrate 26. Node 14 is tied to floating gate 28 and is isolated from substrate 26 by insulation layer 30 (typically a layer silicon dioxide gate oxide).

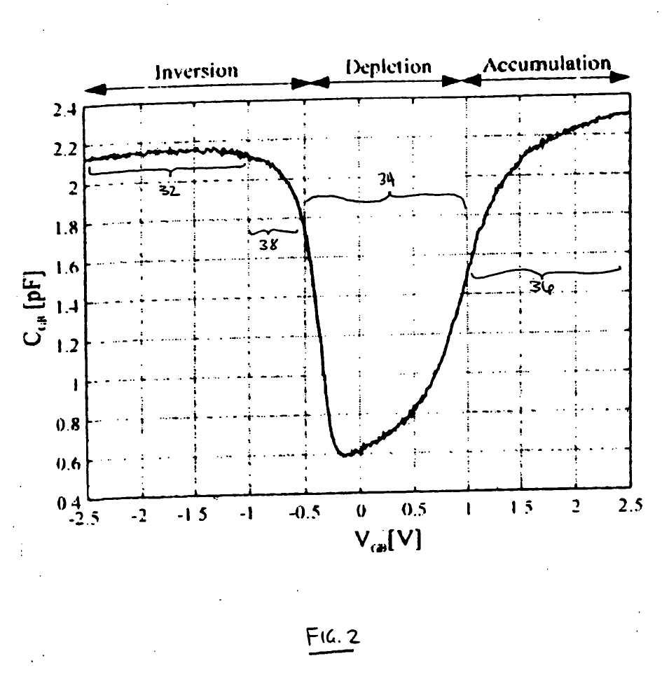

FIG. 2 is a plot of the typical CV (capacitance vs. voltage) characteristic of a floating gate pMOS capacitor in 0.25 μm CMOS with a 5 nm gate oxide thickness between the substrate and the floating gate. (This plot is taken from FIG. 1 of Tille, T., et al., A 1.8-V MOSFET-Only ΣΔ Modulator Using Substrate Biased Depletion-Mode MOS Capacitors in Series Compensation, IEEE Journal of Solid-State Circuits, vol. 36, no. 7, p. 1041, (Jul. 7, 2001). MOS capacitors exhibit a relatively large variation in capacitance dependent upon the voltage differential between the gate and the channel. The gate to channel capacitance varies with the applied voltage in all areas of operation. For example, the MOS capacitor plotted in FIG. 2 exhibits fairly constant capacitance in strong inversion mode 32 (i.e., at a bias of about −1.0 V to about −2.5 V), fairly nonlinear capacitance change as a function of applied voltage in depletion mode 34 (i.e., at a bias of about −0.5 V to about +1.0 V), and a fairly linear change of capacitance with applied voltage in accumulation mode 36 (i.e., at a bias of about +1.0 V to about +2.5 V). A similar response exists in the light inversion mode 38 with an applied voltage in a range of about −0.5 V to about −1.0 V. Accordingly, operation of the variable capacitance MOS capacitor is optimal in either of the regions 36 and 38.

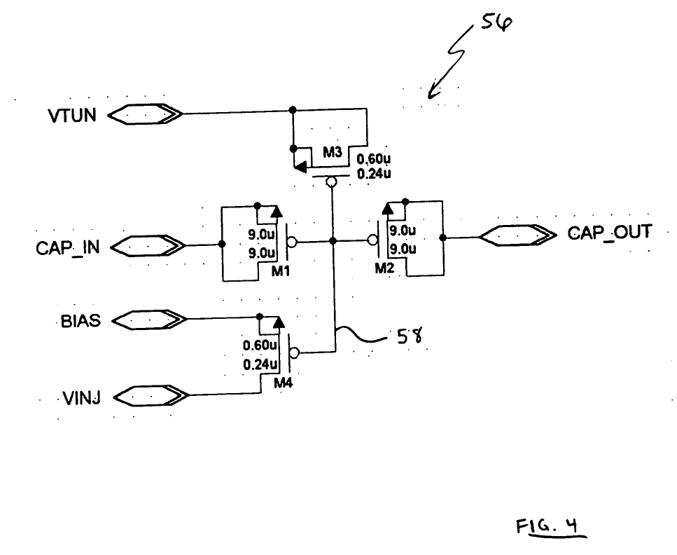

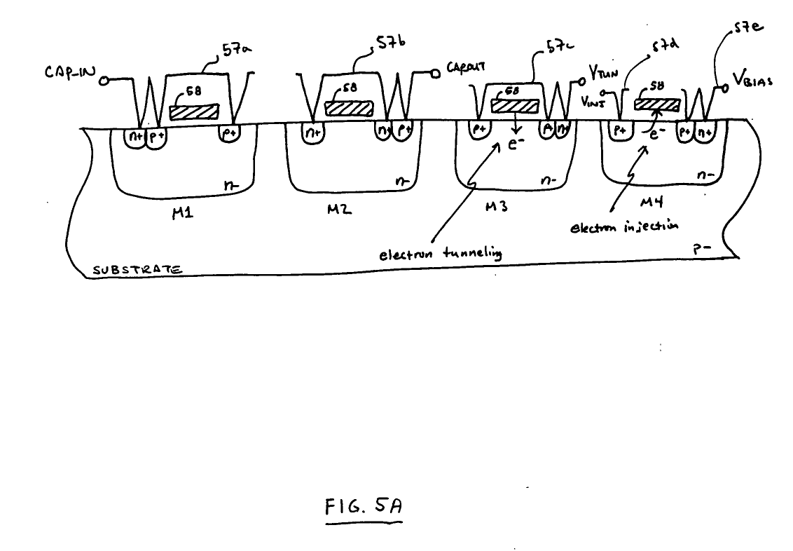

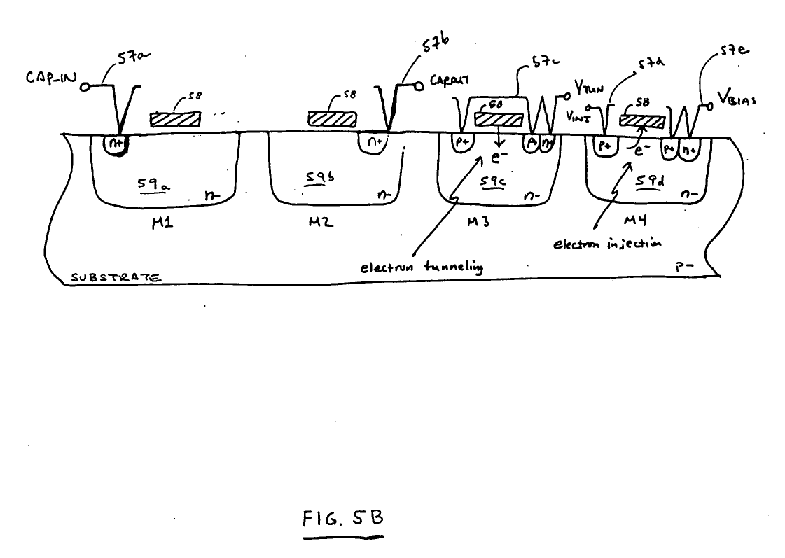

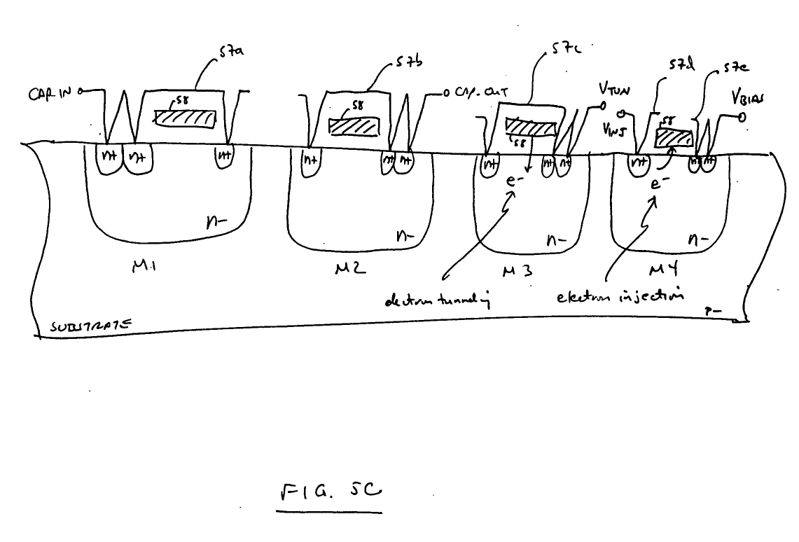

Yoshizawa et al., MOSFET-Only Switched-Capacitor Circuits in Digital CMOS Technology, IEEE Journal of Solid State Circuits, vol. 34, no. 6, pp. 734-747, June 1999, recognized that the non-linearities in capacitance as a function of voltage for MOS capacitors could be reduced or eliminated by coupling a plurality of MOS capacitors in series. Accordingly, where high linearity is desired, a pair of MOS capacitors may be connected in series (see, e.g., FIGS. 4 and 5, infra).

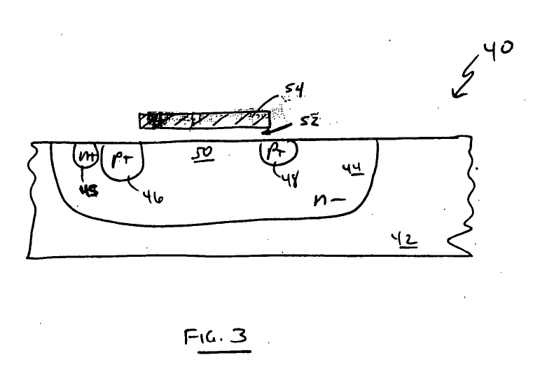

FIG. 3 is an elevational cross sectional drawing of a pFET floating gate transistor 40 as may be used herein to realize the various transistors of the MOS floating gate variable capacitor. The pFET synapse transistor 40 can be fabricated using conventional CMOS fabrication technology and requires no special process steps. It includes a p− substrate 42 and an n-well region 44 disposed in substrate 42. Within n− well 44 are an n+ region 45 for well contact, a p+ source region 46 and a p+ drain region 48. The substrate is preferably p− doped to a level in a range of about 1×10⁵ dopants/cc to about 1×10¹⁶ dopants/cc; the n− well 44 is preferably doped to a level in a range of about 1×10¹⁶ dopants/cc to about 1×10¹⁹ dopants/cc; the n+ region 45 is preferably heavily doped to a level in a range of about 1×10¹⁹ dopants/cc and about 5×10²⁰ dopants/cc; and the p+ regions 46 and 48 are preferably heavily doped to a level in a range of about 1×10¹⁹ dopants/cc to about 5×10²⁰ dopants/cc.

As discussed above, the pFET synapse transistor 40 of FIG. 3 is formed in a p− doped substrate 42 although those of ordinary skill in the art will now realize that it could as easily be formed as a thin film transistor (TFT) above the substrate, or on an insulator (SOI) or on glass (SOG). Essentially, any process capable of forming pFETs and nFETs will work.

A channel 50 is formed between source 46 and drain 48. Over channel 50 is disposed a high quality gate oxide (typically SiO₂) 52 of a thickness commensurate with the voltages to be used in the application. In accordance with one embodiment of the present invention, the gate oxide 52 has a thickness in a range of about 30 angstroms to about 150 angstroms in the region above the channel 50. Over gate oxide layer 52 above channel 50 is disposed floating gate 54. When drain 48 has a sufficiently negative voltage relative to source 46, positively charged holes will be accelerated in channel 50 toward drain 48 and will impact with the crystalline lattice in the region of drain 48 creating an electron-hole pair. The electron is then repelled by the relatively negative E drain 48 is thereby injected, if scattered upward, across the gate oxide layer 52 onto floating gate 54.

Turning now to FIGS. 4 and 5A, a schematic diagram (FIG. 4) and a cross sectional elevational diagram (FIG. 5A) of a complete MOS floating gate variable capacitor circuit is shown. In accordance with this embodiment of the present invention, the MOS floating gate variable capacitor 56 is a circuit comprising at least four devices. These are labeled M1, M2, M3 and M4. M1, M2, M3 and M4 all share the same floating gate 58 formed from a poly 1 layer (heavily doped conductive polysilicon). M1 and M2 are a pair of relatively large (9 μm×9 μm) pFET transistors as described above. M1 and M2 are designed to be substantially larger than M3 and M4 and to have correspondingly larger capacitance so that the parasitic capacitance effects of M3 and M4 are overwhelmed by the much larger capacitance of M1 and M2. Since in a plate capacitor, capacitance is a function of area, the example shown in FIG. 4 has the area of the M1 and M2 capacitors approximately 500 times the area of the M1 and M2 capacitors. They should be substantially the same size as one another and may be connected so that drain, source and well contact are coupled together as shown. Two or more of these devices can be series connected as shown in order to reduce the nonlinearity discussed above. In many cases, two will be sufficient.

M3 is a tunneling junction device with drain, source and well contact coupled together as shown. It need not be as large as M1 and M2 and, in one embodiment, may be 0.24 μm×0.60 μm. M4 is an injection device of similar size to device M3 configured as described above.

The MOS floating gate variable capacitor 56 has five terminals: Vtun (the tunneling voltage); Vinj (the injection voltage); Bias (the bias voltage applied to the injector M4); Cap_In and Cap_Out (the terminals across which the variable capacitance appears).

The tunneling junction M3 comprises a shorted pFET in an n− well for two primary reasons. First, a lightly-doped n− well can accommodate relatively high positive voltage without pn-junction breakdown to the substrate. Second, a shorted pFET in an n− well is a valid structure (that is, it satisfies the design rules) in any CMOS process.

Key features of the MOS floating gate variable capacitor 56 are: (a) relatively high voltages applied to the tunneling junction M3 tunnel electrons off the common floating gate 58; (b) relatively large drain-to-source voltages at M4 cause IHEI at the drain of M4, injecting electrons onto the common floating gate 58. Those of ordinary skill in the art will now realize that other mechanisms for injecting charge onto the floating gate may also be used, including tunneling. In operation, the large value capacitors M1 and M2 are biased either in inversion (38) or accumulation (36). By varying the amount of floating-gate charge, the total series capacitance of M1 and M2 may be adjusted by changing the voltage across the individual capacitors. In this manner, two capacitors may be adjusted to set their values equal to one another.

Electron injection is induced by applying a negative voltage (e.g., −2.5V) to M4's drain. The power supply may be located either off-chip or on-chip and provided by conventional on-chip charge pumps.

Conventional metalization provides the connections 57a, 57b, 57c, 57d and 57e as shown in FIGS. 5A, 5B and 5C.

Turning now to FIG. 5B, an alternative embodiment of the present invention is illustrated. Here the capacitors operate in the accumulation region and thus do not require source or drain regions. The capacitance appears between the common floating gate 58 and the wells 59a and 59b, respectively. In other relevant respects the device operates as described above in conjunction with FIG. 5A.

Turning now to FIG. 5C, yet another alternative embodiment of the present invention is illustrated. Here the substrate is p− doped, the wells are all n− doped and the well, source and drain contacts are all n+ doped (the well contact may be omitted). Heavily doped n− type poly is used for the floating gate. This embodiment will work as well for variable capacitor elements.

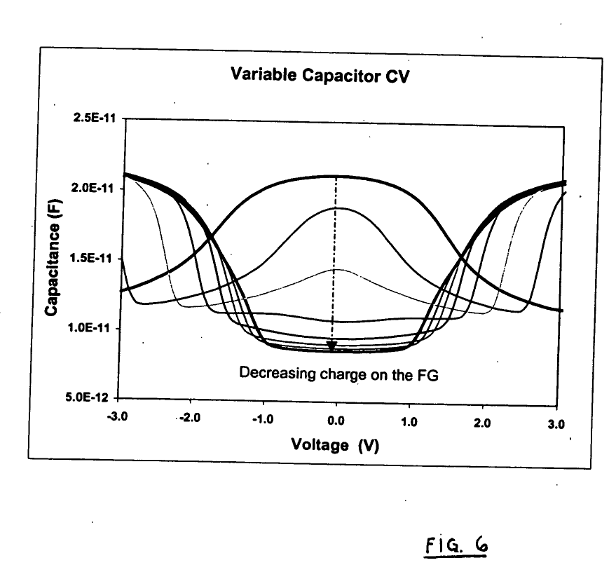

Turning now to FIG. 6, a series of high frequency (100 kHz) CV curves are shown for a test chip embodying a variable capacitor in accordance with one embodiment of the present invention having different amounts of charge on the floating gate. These devices were built using a conventional 0.18 micron fabrication process. The variable capacitor includes back-to-back series connected MOSCAPs each having an area of about 8100 square microns. The MOSCAPs are coupled together at a floating gate. Charge is added to the floating gate with an injection transistor in a source follower configuration and charge is removed with a tunneling junction device.

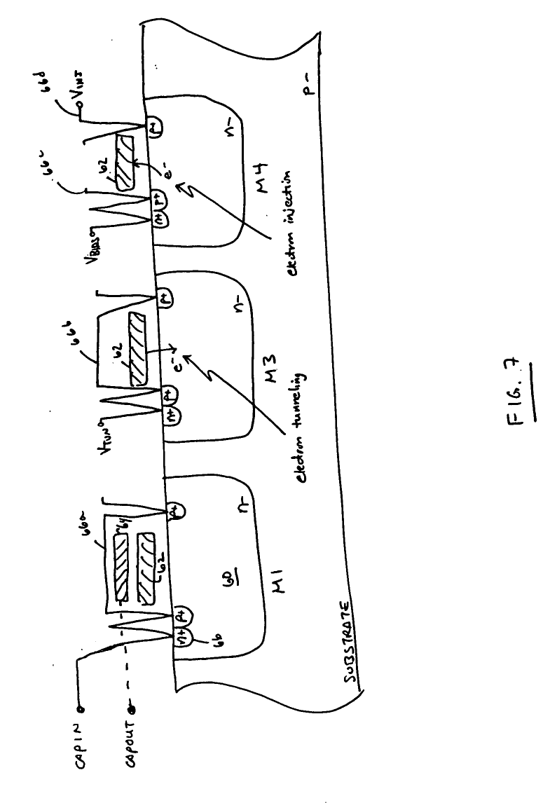

Turning now to FIG. 7, another alternative embodiment of the present invention is illustrated. In accordance with the embodiment of FIG. 7, a double-poly version of the invention is presented. In this version, a MOS device M1 forms a first capacitor having one plate in the well 60 of MOS device M1 and a second plate at the floating gate 62. A second capacitor is formed between a second gate formed in the poly 2 layer 64 and the common floating gate 62. The two capacitors are series connected at the floating gate and charge transport onto and off of the floating gate is handled as in the device illustrated at FIG. 5 and discussed above. In this case, the capacitance between the first polysilicon layer and the second polysilicon layer remains fixed and only the capacitance between the first polysilicon layer and the well is variable. However, the capacitance across the two capacitor plates, comprised of the well connection 66 of transistor M1 and the second polysilcon layer 64 remains variable. Note that this embodiment may also be modified along the lines of the embodiment shown in FIG. 5B (source and drain on the capacitor devices omitted) and discussed above.

As in the embodiment illustrated in FIG. 5A, conventional metalization provides the connections 66a, 66b, 66c and 66d shown in FIG. 7.

While silicon dioxide (SiO₂) is contemplated to be a common dielectric for use as the dielectric in isolating the floating gates of the present invention from each other and from the substrate and its wells, other dielectric materials may be used alone, or in combination with silicon dioxide. For example, any of the following could also be used: nitrided oxide, nitride, oxide/nitride composite, titanium oxide, tantalum oxide, zirconium oxide, hafnium oxide, lanthanum oxide (or any oxide of a lanthanide), titanium silicate, tantalum silicate, zirconium silicate, hafnium silicate and lanthanum silicate (or any silicate of a lanthanide) and composite or multilayer structures thereof. These alternative dielectrics generally provide higher dielectric constants and can therefore be utilized in thinner layers than silicon dioxide.

It should also be noted that the “metal” of the MDS (metal dielectric semiconductor) devices referred to herein may also include conductive polysilicon as well as more traditional “metals” such as aluminum, copper, titanium, and the like.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims.

1. A variable capacitor comprising:
a floating gate;
a first floating gate device and a second floating gate device, said first floating gate device and said second floating gate device having said floating gate as a common floating gate;
a charge injector disposed to inject charge onto said floating gate; and
a tunneling junction disposed to tunnel charge off of said floating gate,
wherein a capacitance of said first and second floating gate devices is varied by controlling charge on said floating gate.

2. A variable capacitor in accordance with claim 1, wherein said charge injector injects electrons.

3. A variable capacitor in accordance with claim 2, wherein said injection of electrons is accomplished, at least in part, utilizing the mechanism of impact ionized hot electron injection.

4. A variable capacitor in accordance with claim 1, wherein said tunneling junction tunnels electrons.

5. A variable capacitor in accordance with claim 4, wherein said tunneling of electrons is accomplished, at least in part, utilizing the mechanism of Fowler Nordheim tunneling.

6. A variable capacitor in accordance with claim 1, wherein said first floating gate device is a floating gate transistor.

7. A variable capacitor in accordance with claim 6, wherein said second floating gate device is a floating gate transistor.

8. A variable capacitor in accordance with claim 7, wherein a first source and drain of said first floating gate transistor are coupled together and a second source and drain of said second floating gate transistor are coupled together.

9. A variable capacitor comprising:
a semiconductor substrate including a first well and a second well;
a floating gate;
a first floating gate transistor formed in said first well and a second floating gate transistor formed in said second well, said first floating gate transistor and said second floating gate transistor having said floating gate as a common floating gate, said first floating gate transistor and said second floating gate transistor each having a corresponding source and drain;
a first capacitance appearing between said first well and said floating gate;
a second capacitance appearing between said second well and said floating gate;
a charge injector disposed to inject charge onto said floating gate; and
a tunneling junction disposed to tunnel charge off of said floating gate.

10. A variable capacitor comprising:
a semiconductor substrate including a first well;
a floating gate;
a first floating gate transistor formed in said first well and a second floating gate transistor formed in said second well, said first floating gate transistor and said second floating gate transistor having said floating gate as a common floating gate, said first floating gate transistor and said second floating gate transistor each having a corresponding source and drain;
a first capacitance appearing between said first well and said floating gate;
a second capacitance appearing between said second well and said floating gate;
a charge injector disposed to inject charge onto said floating gate; and
a tunneling junction disposed to tunnel charge off of said floating gate.

11. A variable capacitor in accordance with claim 8, wherein said first floating gate transistor and said second floating gate transistor are MOSFETs.

12. A variable capacitor in accordance with claim 8, wherein said first floating gate transistor and said second floating gate transistor are pFETs.

13. A variable capacitor in accordance with claim 12, wherein said pFETs are disposed in a semiconductor substrate.

14. A variable capacitor in accordance with claim 13, wherein said floating gate is fabricated from polysilicon isolated from said semiconductor substrate by a layer of silicon dioxide.

15. A variable capacitor comprising:
a floating gate disposed over and isolated from a semiconductor substrate by a layer of silicon dioxide;
a first floating gate transistor and a second floating gate transistor, said first floating gate transistor and said second floating gate transistor having said floating gate as a common floating gate, a first source and drain of said first floating gate transistor being coupled together and a second source and drain of said second floating gate transistor being coupled together;
a charge injector transistor disposed to inject charge onto said floating gate; and
a tunneling junction transistor disposed to tunnel charge off of said floating gate, said tunneling junction transistor having its source and drain coupled together.

16. A MOS floating gate variable capacitor, comprising:
a p− doped substrate;
a floating gate disposed above said substrate and insulated therefrom;
a first n− well and a second n− well disposed in said substrate;
a first and a second p+ doped region disposed in said first n− well;
a third and a fourth p+ doped region disposed in said second n− well,
said first and second p+ doped regions coupled to one another and providing a first capacitor contact, said third and fourth p+ regions coupled together and forming a second capacitor contact;
an injector disposed to inject charge onto said floating gate; and
a tunneling junction disposed to remove charge from said floating gate.

17. A method for providing a variable capacitance, said method comprising:
providing a first and a second floating gate pFET transistor in a semiconductor substrate, said pFET transistors each having a common floating gate and their respective source, drain and well contact terminals coupled together to provide first and second capacitor contacts;
injecting charge onto said common floating gate to adjust a capacitance between said first and second capacitor contacts; and
tunneling charge from said common floating gate to adjust a capacitance between said first and second capacitor contacts.

18. A method in accordance with claim 17, wherein said injecting is performed with a synapse transistor wired as an injector and having as its floating gate said common floating gate.

19. A method in accordance with claim 17, wherein said tunneling is performed with a synapse transistor wired as a tunneling junction and having as its floating gate said common floating gate.

20. A method for adjusting the capacitance of a MOS floating gate variable capacitor, the MOS floating gate variable capacitor having:
a floating gate;
a first floating gate transistor and a second floating gate transistor, said first floating gate transistor and said second floating gate transistor having said floating gate as a common floating gate, a first source and drain of said first floating gate transistor being coupled together and providing a first capacitor contact and a second source and drain of said second floating gate transistor being coupled together and providing a second capacitor contact;
a charge injector disposed to inject charge onto said floating gate; and
a tunneling junction disposed to tunnel charge off of said floating gate, said method comprising:
adding charge to said floating gate by injecting charge with said injector; and
removing charge from said floating gate by tunneling charge with said injector, changes in the charge stored on said floating gate causing a change in the capacitance between said first capacitor contact and said second capacitor contact.

21. A method in accordance with claim 20, wherein said charge injector includes an injection transistor having a source and a drain and said adding charge includes applying a relatively negative potential to said drain of said injection transistor.

22. A MOS floating gate variable capacitor, comprising:
charge storage means;
a first transistor and a second transistor, said first transistor and said second transistor coupled to said charge storage means, said first transistor having a first capacitor contact and said second transistor having a second capacitor contact;
charge injection means for injecting charge onto said charge storage means; and
charge removal means for removing charge from said charge storage means.

23. A variable capacitor comprising:
a first capacitor having a first and second terminal;
a second capacitor having a first and second terminal;
a floating node coupling said second terminal of said first capacitor and said second terminal of said second capacitor; and
a charge injector for controlling the charge stored on the floating node.

24. A variable capacitor in accordance with claim 23, wherein said first capacitor is a metal/dielectric/semiconductor (MDS) device formed on a semiconductor substrate wherein its metal portion is part of said floating node.

25. A variable capacitor in accordance with claim 24, wherein said metal portion of the MDS device comprises polysilicon.

26. A variable capacitor in accordance with claim 25, wherein said MDS device is a metal/oxide/semiconductor (MOS) device.

27. A variable capacitor in accordance with claim 23, wherein said first and second capacitors are metal/dielectric/semiconductor (MDS) devices formed on a semiconductor substrate having their metal portions comprise said floating node.

28. A variable capacitor in accordance with claim 27, wherein said metal portions of the MDS devices comprises polysilicon.

29. A variable capacitor in accordance with claim 28, wherein said MDS devices are metal/oxide/semiconductor (MOS) devices.

30. A variable capacitor in accordance with claim 29 wherein said charge injector adds charge to and removes charge from the floating node using bidirectional tunneling, including Fowler-Nordheim tunneling, direct tunneling, and Frenkel-Poole tunneling.

31. A variable capacitor in accordance with claim 29 wherein said charge injector is a transistor which injects charge onto the floating node, said variable capacitor further comprising:
a tunnel junction electrically coupled to said floating node and to a substrate for transferring charge from the floating node to the substrate.

32. A variable capacitor, comprising:
a substrate of a first conductivity type;
a first well disposed in said substrate, said first well of said second conductivity type;
a floating gate;
a first dielectric material disposed between said floating gate and said first well;
a conductive gate separated from said floating gate by a second dielectric material;
a first capacitor formed between said first well and said floating gate;
a second capacitor formed between said conductive gate and said floating gate, said first and second capacitor series coupled at said floating gate;
a charge injector disposed to inject charge onto said floating gate; and
a tunneling junction disposed to tunnel charge off of said floating gate.

33. A variable capacitor in accordance with claim 32 wherein:
said first dielectric material and said second dielectric material are the same.

34. A variable capacitor in accordance with claim 33 wherein:
said dielectric material comprises an oxide material.

35. A variable capacitor in accordance with claim 34 wherein:
said conductive gate is formed from heavily doped polysilicon.

36. A variable capacitor in accordance with claim 35 wherein:
said floating gate is formed from heavily doped polysilicon.

37. A variable capacitor in accordance with claim 32 wherein:
at least one of said first and second dielectric materials comprises one or more materials selected from the group consisting of: nitrided oxide, nitride, oxide/nitride composite, titanium oxide, tantalum oxide, zirconium oxide, hafnium oxide, lanthanum oxide, titanium silicate, tantalum silicate, zirconium silicate, hafnium silicate and lanthanum silicate and a composite or multilayer structure comprising two or more of the foregoing materials.

38. A variable capacitor in accordance with claim 8, wherein said first floating gate transistor and said second floating gate transistor are nFETs.

39. A variable capacitor in accordance with claim 38, wherein said nFETs are disposed in a semiconductor substrate.

40. A MOS floating gate variable capacitor, comprising:
a semiconductor substrate;
a floating gate disposed above said substrate and insulated therefrom;
a first p− well and a second p− well disposed in said substrate;
a first and a second n+ doped region disposed in said first p− well;
a third and a fourth n+ doped region disposed in said second p− well, said first and second n+ doped regions coupled to one another and providing a first capacitor contact, said third and fourth n+ regions coupled together and forming a second capacitor contact;
an injector disposed to inject charge onto said floating gate; and
a tunneling junction disposed to remove charge from said floating gate.

41. A method for providing a variable capacitance, said method comprising:
providing a first and a second floating gate nFET transistor in a semiconductor substrate, said nFET transistors each having a common floating gate and their respective source, drain and well contact terminals coupled together to provide first and second capacitor contacts;
injecting charge onto said common floating gate to adjust a capacitance between said first and second capacitor contacts; and
tunneling charge from said common floating gate to adjust a capacitance between said first and second capacitor contacts.

42. A method in accordance with claim 41, wherein said injecting is performed with a synapse transistor wired as an injector and having as its floating gate said common floating gate.

43. A method in accordance with claim 41, wherein said tunneling is performed with a synapse transistor wired as a tunneling junction and having as its floating gate said common floating gate.

44. A variable capacitor comprising:
a floating gate;
an electron injector disposed to inject electrons onto said floating gate;
a tunneling junction disposed to tunnel electrons off of said floating gate;
a first floating gate device having a first terminal; and
a second floating gate device having a second terminal,
said first and second floating gate devices having said floating gate as a common floating gate and exhibiting a variable capacitance across said first and second terminals, the variable capacitance responsive to an amount of charge stored on said floating gate.

45. A variable capacitor in accordance with claim 44, wherein said injection of electrons is accomplished, at least in part, utilizing the mechanism of impact ionized hot electron injection.

46. A variable capacitor in accordance with claim 44, wherein said tunneling of electrons is accomplished, at least in part, utilizing the mechanism of Fowler-Nordheim tunneling.

47. A variable capacitor in accordance with claim 44, wherein said first floating gate device is a floating gate transistor.

48. A variable capacitor in accordance with claim 47, wherein said second floating gate device is a floating gate transistor.

49. A variable capacitor in accordance with claim 48, wherein a first source and drain of said first floating gate transistor are coupled together and a second source and drain of said second floating gate transistor are coupled together.
